(19) United States
(12) Patent Application Publication
(10) Pub. No.: US 2019/0214357 A1
(43) Pub. Date: Jul. 11, 2019

(54) SEMICONDUCTOR DEVICE HAVING A BUMP STRUCTURE AND METHOD FOR MANUFACTURING THE SAME

(71) Applicant: CHIPBOND TECHNOLOGY CORPORATION, Hsinchu (TW)

(72) Inventors: Chun-Te Lee, Hsinchu County (TW); Ming-Sheng Liu, Hsinchu City (TW)

(21) Appl. No.: 15/952,807

(22) Filed: Apr. 13, 2018

(30) Foreign Application Priority Data
Jan. 5, 2018 (TW) 107100404

(51) Int. Cl. H01L 23/00

(52) U.S. Cl. CPC H01L 24/13; H01L 24/03; H01L 24/05; H01L 24/11; H01L 2224/0401; H01L 2224/11005; H01L 2224/05184; H01L 2224/1181; H01L 2224/13006; H01L 2224/05644; H01L 2224/13144; H01L 2224/05166; H01L 2224/11831

(57) ABSTRACT

A method for manufacturing a semiconductor device includes an extra etching process. A bump or a UBM layer is etched additionally in the extra etching process after forming the semiconductor device such that the semiconductor device can conform to the standard of performance and appearance.

### FIELD OF THE INVENTION

This invention relates to a semiconductor device and a method for manufacturing the same, and more particularly relates to a semiconductor device having a bump structure and a method for manufacturing the same.

### BACKGROUND OF THE INVENTION

Bump structure formation is a critical process in the flip-chip technology. The conventional bump structure for electrical connecting the chip and the substrate is formed on the chip through photoresist patterning process, bump plating process and etching process. Owing to the chip can be flipped to connect the substrate, the semiconductor device manufactured by the conventional flip-chip process has the advantages of high component density, high cooling ability and low costs, and can reduce the overall IC size significantly. For these reasons, the flip chip technology is one of the important IC package processes and the manufacturing yield improvement for the bump structure is the key point of the flip chip technology.

### SUMMARY

The primary object of the present invention is to additionally etch the bump or the UBM layer to further remove the metal residue remained during the normal etching, so as to ensure the appearance and performance of the semiconductor device conform to the standard.

The method for manufacturing a semiconductor device having a bump structure of the present invention comprises the steps of: providing a substrate having a conducting pad and a protecting layer, the conducting pad is exposed by a through hole of the protecting layer; forming a UBM layer on the substrate, the UBM layer overlays the protecting layer and the conducting pad exposed by the through hole; forming a patterned photoresist layer on the UBM layer, an opening of the patterned photoresist layer exposes the UBM layer; forming a bump in the opening of the patterned photoresist layer, the bump is electrically connected to the UBM layer; stripping the patterned photoresist layer, a side wall of the bump and the UBM layer not overlaid by the bump are exposed; performing an etching process on the UBM layer, the UBM layer is etched for exposing the protecting layer by using the bump as a mask; and performing an extra etching process on the bump or the UBM layer, the extra etching process is used for adjusting a size of the bump, removing metallic residues or contaminates on the bump.

The extra etching process for the bump or the UBM layer can eliminate possible problems of irregular size, remained metal and surface contamination of the semiconductor device. As a result, the semiconductor device can be conformed to the standards of performance and appearance to improve the manufacturing yield.

### DESCRIPTION OF THE DRAWINGS

FIG. 1 is a flowchart illustrating steps of a method for manufacturing a semiconductor device having a bump structure in accordance with one embodiment of the present invention.

FIGS. 2 to 11 are cross-section view diagrams illustrating the method for manufacturing a semiconductor device having a bump structure in accordance with one embodiment of the present invention.

### DETAILED DESCRIPTION OF THE INVENTION

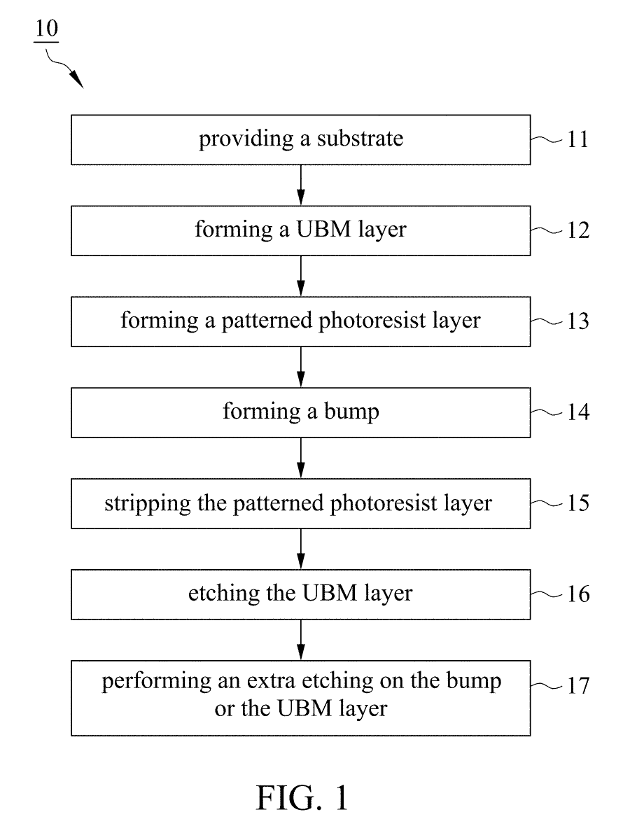

With reference to FIG. 1, a method 10 for manufacturing a semiconductor device having a bump structure in accordance with one embodiment of the present invention includes step 11 of providing a substrate, step 12 of forming a UBM layer, step 13 of forming a patterned photoresist layer, step 14 of forming a bump, step 15 of stripping the patterned photoresist layer, step 16 of performing an etching process on the UBM layer and step 17 of performing an extra etching process on the bump or the UBM layer.

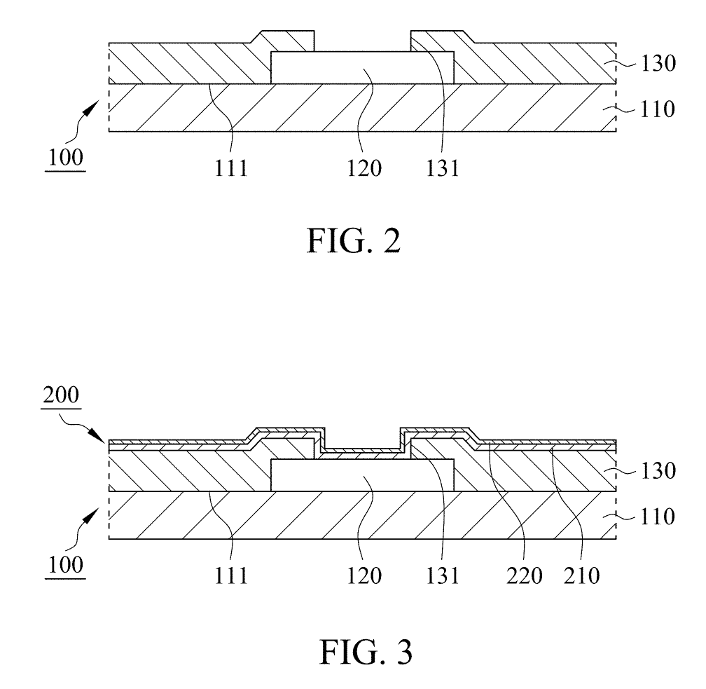

With reference to FIGS. 1 and 2, a substrate 100 provided in the step 11 includes a main body 110, a conducting pad 120 and a protecting layer 130.

The conducting pad 120 is located on a surface 111 of the main body 110 and is provided for the electrical connection between the internal elements (not shown) of the main body 110 and other electronic components/conductors. The protecting layer 130 made of an insulating material overlays the surface 111 of the main body 110 and a part of the conducting pad 120 to protect the surface 111 of the main body 110. The protecting layer 130 has a through hole 131 that exposes the conducting pad 120. In this embodiment, the main body 110 is made of silicon, gallium arsenide (GaAs) or other semiconductor materials, the substrate 100 includes a plurality of conducting pads 120 made of metal (e.g. aluminum and copper) and the protecting layer 130 has a plurality of through holes 131 that each expose one of the conducting pads 120.

With reference to FIGS. 1 and 3, a UBM (under bump metallurgy) layer 200 is formed on the substrate 100 in the step 12. The UBM layer 200 overlays the protecting layer 130 and the conducting pad 120 exposed by the through hole 131. In this embodiment, the UBM layer 200 includes a first metal layer 210 and a second metal layer 220 which are formed on the substrate 100 by vapor deposition or sputtering, respectively. In details, the first metal layer 210 is formed on the substrate 100 and then the second metal layer 220 is formed on the first metal layer 210 such that the first metal layer 210 is located between the substrate 100 and the second metal layer 220. The first metal layer 210 that contacting with the protecting layer 130 and the conducting pad 120 can be used as an adhesion layer for connecting the conducting pad 120 and other metal materials or used as a barrier layer to avoid the metal ion migration of the second metal layer 220. The second metal layer 220 contacted with the first metal layer 210 is a seed layer used to define the patterns of bumps formed laterally.

In this embodiment, the first metal layer 210 and the second metal layer 220 are, but not limit to, made of titanium-tungsten (TiW) alloy and gold, respectively.

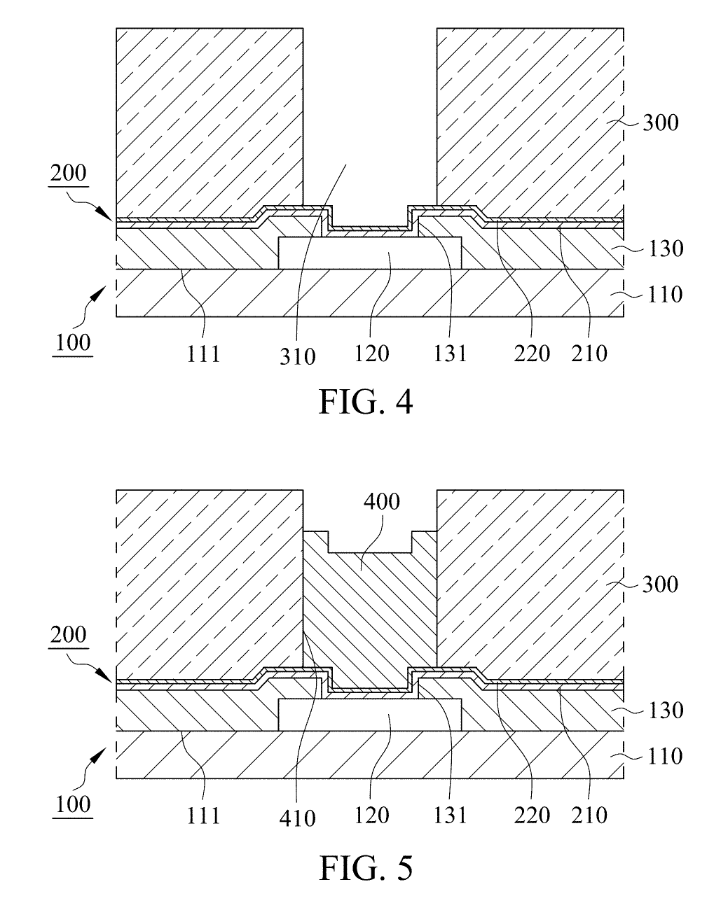

With reference to FIGS. 1 and 4, a patterned photoresist layer 300 is formed on the UBM layer 200 in the step 13 and an opening 310 of the patterned photoresist layer 300 exposes the UBM layer 200. The steps of forming the patterned photoresist layer 300 includes: (i) coating a photoresist material on the UBM layer 200; (ii) using a mask to pattern the photoresist material in exposure process for defining the pattern of the photoresist material; and (iii) forming the patterned photoresist layer 300 from the exposed photoresist material in development process. The positive and negative photoresist materials both can be used to form the patterned photoresist layer 300.

With reference to FIGS. 1 and 5, a bump 400 is formed in the opening 310 of the patterned photoresist layer 300 in the step 14. The bump 400 is formed on the second metal layer 220 of the UBM layer 200 and electrically connected to the UBM layer 200. The bump 400 can be manufactured in the opening 310 of the patterned photoresist layer 300 by vapor deposition, plating or printing. In this embodiment, the metal same with the second metal layer 220 (e.g. gold) is plated in the opening 310 of the patterned photoresist layer 300 to form the bump 400.

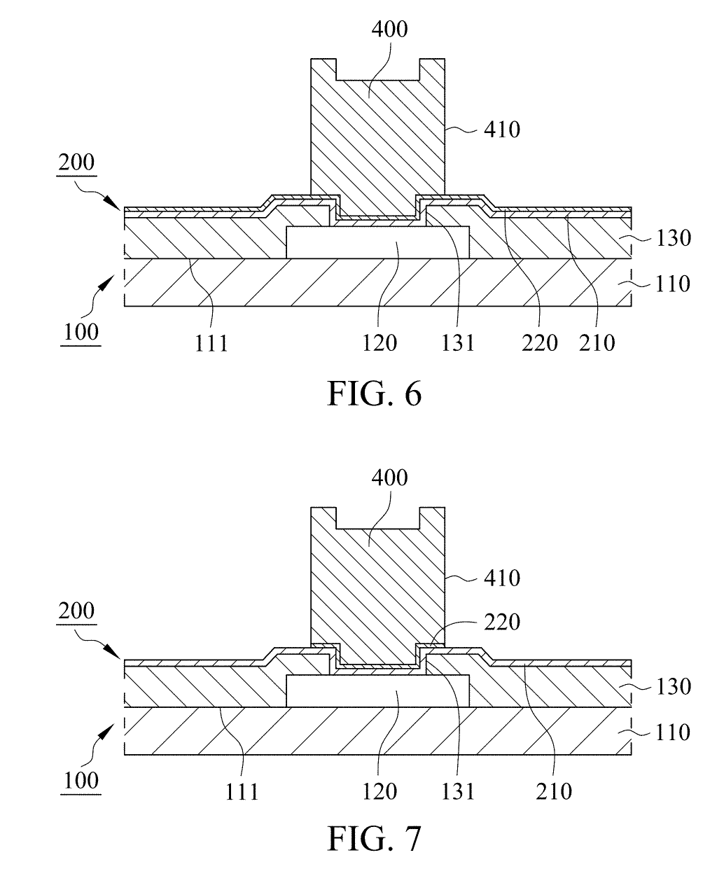

With reference to FIGS. 1 and 6, in the step 15, the patterned photoresist layer 300 is stripped to expose a side wall 410 of the bump 400 and the UBM layer 200 not be overlaid by the bump 400. Preferably, the patterned photoresist layer 300 can be stripped from the substrate 100 by soaking and washing in a stripping solution.

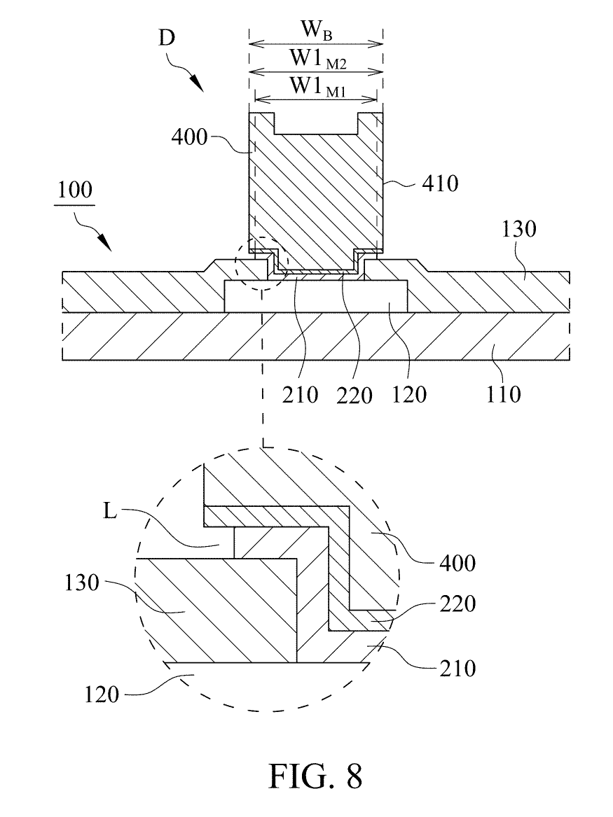

With reference to FIGS. 1, 7 and 8, the UBM layer 200 is etched in an etching process of the step 16 by using the bump 400 as the mask. In the step 16, the UBM layer 200 not be overlaid by the bump 400 is removed to expose the protecting layer 133 so as to form a semiconductor device D having a bump structure. With reference to FIGS. 7 and 8, due to the UBM layer 200 of this embodiment includes the first and second metal layers 210 and 220, the first and second metal layers 210 and 220 not covered by the bump 400 are etched and removed respectively by two etching processes. With reference to FIG. 8, the first metal layer 210 has a first width W1_{M1} and the second metal layer 220 has a first width W1_{M2} after two etching processes, and the first width W1_{M1} of the first metal layer 210 is smaller than the first width W1_{M2} of the second metal layer 220. As a result, there is a concave L formed between the edges of the second metal layer 220 and the protecting layer 130.

With reference to FIG. 1, owing to the appearance and performance of the semiconductor device D may be defective after the step 16, an extra etching process can be performed in the step 17. In order to remove the metal residues, remove the contaminates on the bump 400 or adjust the size of the bump 400, the bump 400 or the UBM layer 200 can be etched additionally in the extra etching process such that the semiconductor device D after the extra etching process is non-defective. In this embodiment, the bump 400 or the UBM layer 200 may be etched additionally in the extra etching process after checking the appearance of the semiconductor device D. Preferably, a further step of checking the semiconductor device D is processed before the step 17 to check whether there is any defect on the semiconductor device D, such as irregular bump size, metallic residues (Au or TiW) or surface contamination.

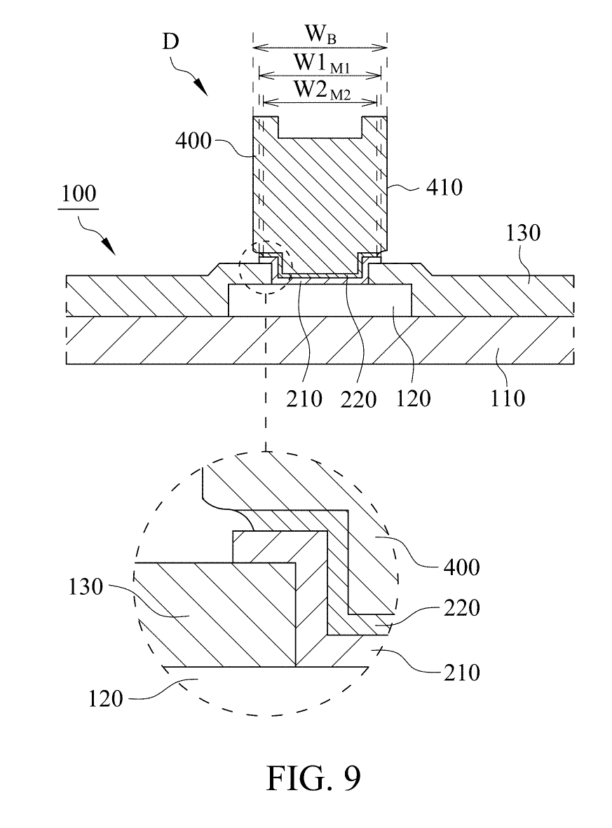

If irregular bump size or surface contamination is checked in the checking process, the bump 400 has to be etched additionally to adjust the size or remove contaminates in the step 17. With reference to FIG. 9, when the bump 400 is etched by using an etching solution, the second metal layer 220 is also etched by the etching solution because the bump 400 and the second metal layer 220 are made of the same material. Furthermore, owing to the concave L formed between the second metal layer 220 and the protecting layer 130 in the step 16 is filled with the etching solution during the extra etching process of the bump 400, the second metal layer 220 is etched quicker than the bump 400 such that a second width W2_{M2} of the second metal layer 220 after the extra etching process is smaller than a width W_{B} of the bump 400 and the first width W1_{M1} of the first metal layer 210.

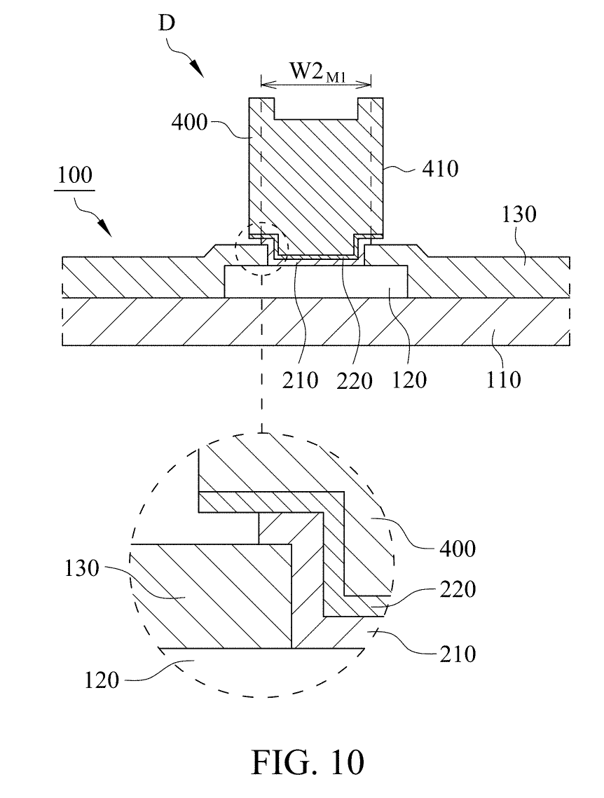

If the TiW residues remained on the semiconductor device D is confirmed in the checking process, means the first metal layer 210 not be covered by the bump 400 is not removed completely and the first metal layer 210 has to be etched additionally in the step 17 to remove the remained first metal layer 210. With reference to FIGS. 8 and 10, owing to the concave L between the second metal layer 220 and the protecting layer 130 is formed after the step 16, the etching solution will stay in the concave L to etch the lateral wall of the first metal layer 210 in the extra etching process, such that the first metal layer 210 after the extra etching process has a second width W2_{M1} smaller than the first width W1_{M1} of the first metal layer 210 before the extra etching process.

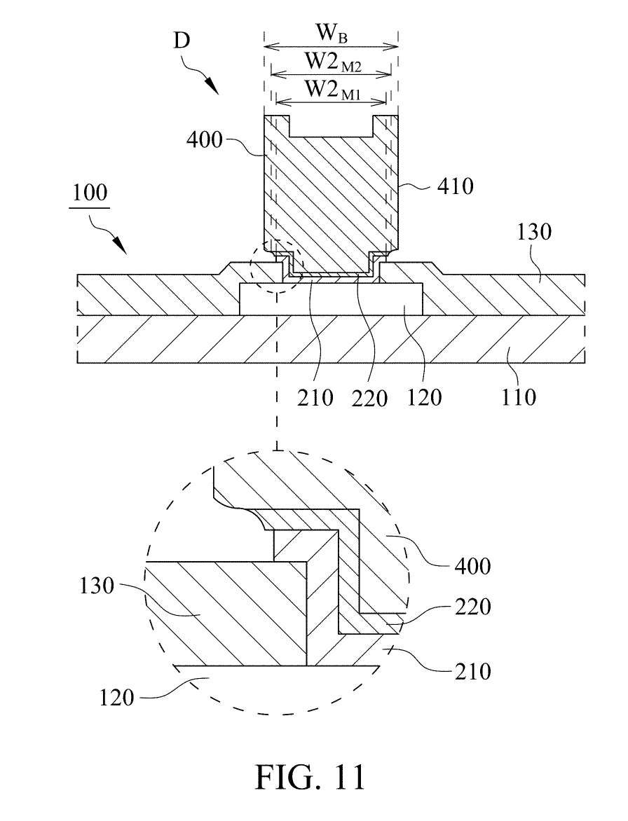

On the other hand, the remained gold confirmed in the checking process means the second metal layer 220 not be covered by the bump 400 is not removed completely, and also means the first metal layer 210 under the second metal layer 220 is not removed. As a result, the step 17 is proceeded to additionally etch the first and second metal layers 210 and 220 to remove the remained first and second metal layers 210 and 220. With reference to FIGS. 8 and 11, although the bump 400 is also etched during the additional etching of the second metal layer 220, the second metal layer 220 is higher in etching rate than the bump 400 due to the etching solution is filled in the concave L, and a second width W2_{M2} of the second metal layer 220 after the extra etching process is smaller than the width W_{B} of the bump 400. Then, the first metal layer 210 is etched additionally. As such the second metal layer 220, the side wall of the first metal layer 210 under the bump 400 is etched by the etching solution in the concave L and a second width W2_{M1} of the first metal layer 210 after the extra etching process is smaller than the second width W2_{M2} of the second metal layer 220 after the extra etching process.

The extra etching process of the bump 400 or the UBM layer 200 in the present invention is provided to effectively eliminate the problems of irregular size, metallic residues and surface contamination of the semiconductor device D, so the appearance and performance of the semiconductor device D can conform to the standard to increase the yield of the semiconductor device D.

While this invention has been particularly illustrated and described in detail with respect to the preferred embodiments thereof, it will be clearly understood by those skilled in the art that is not limited to the specific features shown and described and various modified and changed in form and details may be made without departing from the spirit and scope of this invention.

What is claimed is:

1. A method for manufacturing semiconductor device having bump structure, comprising the steps of:
providing a substrate having a conducting pad and a protecting layer, the conducting pad is exposed by a through hole of the protecting layer;
forming a UBM layer on the substrate, the UBM layer overlays the protecting layer and the conducting pad exposed by the through hole;
forming a patterned photoresist layer on the UBM layer, an opening of the patterned photoresist layer exposes the UBM layer;
forming a bump in the opening of the patterned photoresist layer, the bump is electrically connected to the UBM layer;
stripping the patterned photoresist layer, a side wall of the bump and the UBM layer not overlaid by the bump are exposed;
performing an etching process on the UBM layer, the UMB layer is etched for exposing the protecting layer by using the bump as a mask; and
performing an extra etching process on the bump or the UBM layer, the extra etching process is used for adjusting a size of the bump, removing metallic residues or contaminates on the bump.

2. The method in accordance with claim 1, wherein the UBM layer includes a first metal layer and a second metal layer, the first metal layer is located between the second metal layer and the substrate.

3. The method in accordance with claim 2, wherein the first metal layer and/or the second metal layer is etched during the extra etching process.

4. The method in accordance with claim 3, wherein the first metal layer is made of titanium-tungsten alloy.

5. The method in accordance with claim 3, wherein the second metal layer after the extra etching process has a width that is smaller than a width of the bump.

6. The method in accordance with claim 5, wherein the second metal layer and the bump are made of the same material.

7. The method in accordance with claim 6, wherein the second metal layer and the bump are made of gold.

8. The method in accordance with claim 3, wherein the second metal layer after the extra etching process has a width that is smaller than a first width of the first metal layer after the etching process and larger than a second width of the first metal layer after the extra etching process.

9. The method in accordance with claim 8 further comprising a checking process for the bump and the UBM layer before the extra etching process, wherein the checking process is provided to determine whether there is the irregular bump, the contaminated bump, the remained first metal layer or the remained second metal layer, wherein the bump is etched in the extra etching process when the irregular bump or the contaminated bump is determined, the first metal layer is etched in the extra etching process when the remained first metal layer is determined, and the first metal layer and the second metal layer are etched in the extra etching process when the remained second metal layer is determined.

10. A semiconductor device having bump structure manufactured using the method of claim 1.
